(19) United States
(12) Patent Application Publication
(10) Pub. No.: US 2025/0357279 A1
(43) Pub. Date: Nov. 20, 2025

(54) SEMICONDUCTOR PACKAGE HAVING TWO OR MORE DRIVER DEVICES AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Madhur Bobde, Sunnyvale, CA (US); Long-Ching Wang, Cupertino, CA (US)

(73) Assignee: ALPHA AND OMEGA SEMICONDUCTOR INTERNATIONAL LP, TORONTO (CA)

(21) Appl. No.: 18/666,385

(22) Filed: May 16, 2024

(51) Int. Cl. H01L 23/495; H01L 23/00; H01L 25/065

(52) U.S. Cl. CPC H01L 23/49541; H01L 23/4951; H01L 23/49575; H01L 24/40; H01L 24/48; H01L 24/73; H01L 25/0652; H01L 2224/40137; H01L 2224/40175; H01L 2224/48138; H01L 2224/48175; H01L 2224/73271; H01L 2924/1306; H01L 2924/1426; H01L 2924/1431; H01L 2924/182

(57) ABSTRACT

A semiconductor package comprises a lead frame, two or more low side field-effect transistors (FETs), two or more high side FETs, two or more metal clips, a metal slug, an integrated circuit (IC) controller, and a molding encapsulation. A method for fabricating a semiconductor package comprising the steps of providing a lead frame comprising die paddles; attaching transistors to the die paddles respectively; mounting metal clips; mounting a metal slug and a controller, applying bonding wires; forming a molding encapsulation; and applying a singulation process.

### FIELD OF THE INVENTION

This invention relates generally to a semiconductor package and a method of making the same. More particularly, the present invention relates to the semiconductor package having two or more driver devices and the method of making the same.

### BACKGROUND OF THE INVENTION

Conventional circuit to provide power for a central processing unit (CPU) or a graphics processing unit (GPU) includes a plurality of driver metal-oxide-semiconductors (DrMOSs). The plurality of DrMOSs take space and increase impedance.

U.S. Pat. No. 11,094,617 to Xue et al. disclosed a reduction in size (from 5 mm by 6 mm to 5 mm by 5 mm) of a Buck-Boost power controller comprising at least four field-effect transistors (FETs) in a single package. The instant disclosure further reduces the size to 5 mm by 4 mm by using common Vcc pin, TMON pin, AGND pin, and PVcc pin.

### SUMMARY OF THE INVENTION

The present invention discloses a semiconductor package comprising a lead frame, two or more low side FETs, two or more high side FETs, two or more metal clips, a metal slug, an integrated circuit (IC) controller, and a molding encapsulation.

A method for fabricating a semiconductor package is also disclosed. The method comprises the steps of providing a lead frame comprising die paddles; attaching transistors to the die paddles respectively; mounting metal clips; mounting a metal slug and a controller, applying bonding wires; forming a molding encapsulation; and applying a singulation process.

### BRIEF DESCRIPTION OF THE DRAWINGS

FIG. 1 is a schematic plot of conventional circuit to provide power for a CPU or a GPU.

FIG. 2A is a top perspective view and FIG. 2B is a bottom perspective view of a semiconductor package in examples of the present disclosure.

FIG. 3 is a top perspective view of another semiconductor package in examples of the present disclosure.

FIG. 4 is a flowchart of a process to develop a semiconductor package in examples of the present disclosure.

FIGS. 5A, 5B, 5C, 5D, 5E, 5F, 5G, 5H, 5I, and 5J show perspective views of steps of the process to fabricate the semiconductor package in examples of the present disclosure.

### DETAILED DESCRIPTION OF THE INVENTION

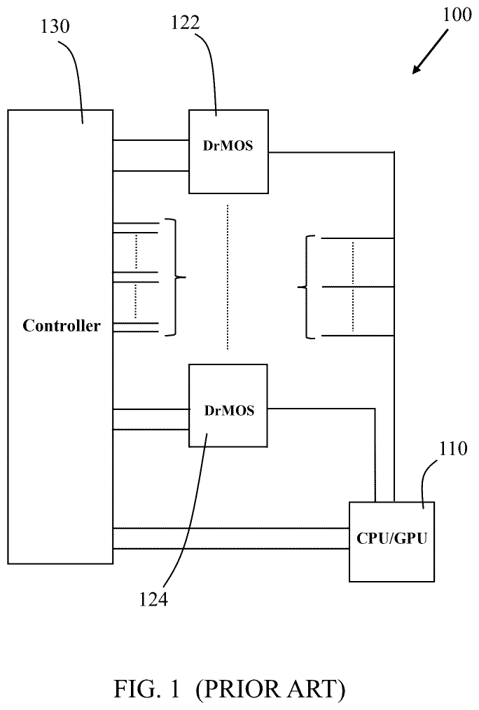

FIG. 1 is a schematic plot of circuit 100 to provide power for a CPU or a GPU 110. The circuit 100 includes a first DrMOS 122, a second DrMOS 124, and a controller 130. The advantage of the instant disclosure is to co-pack the DrMOSs in a single package, to reduce the package size, and to reduce the impedance.

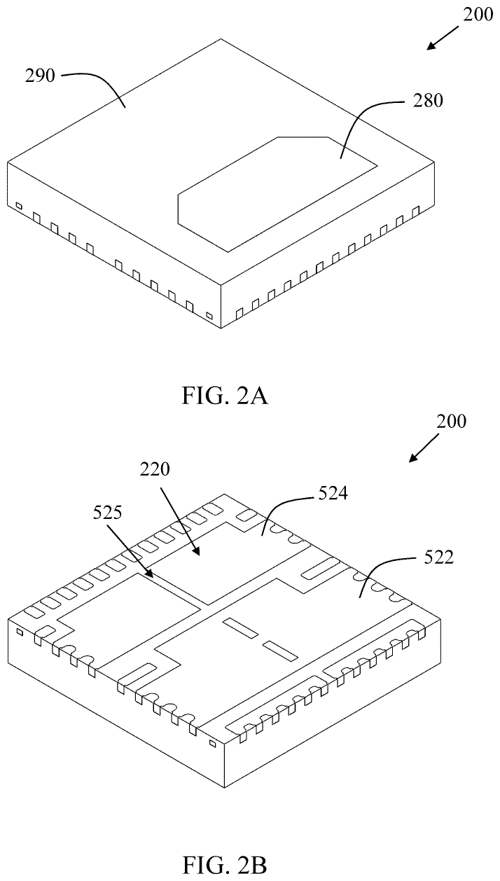

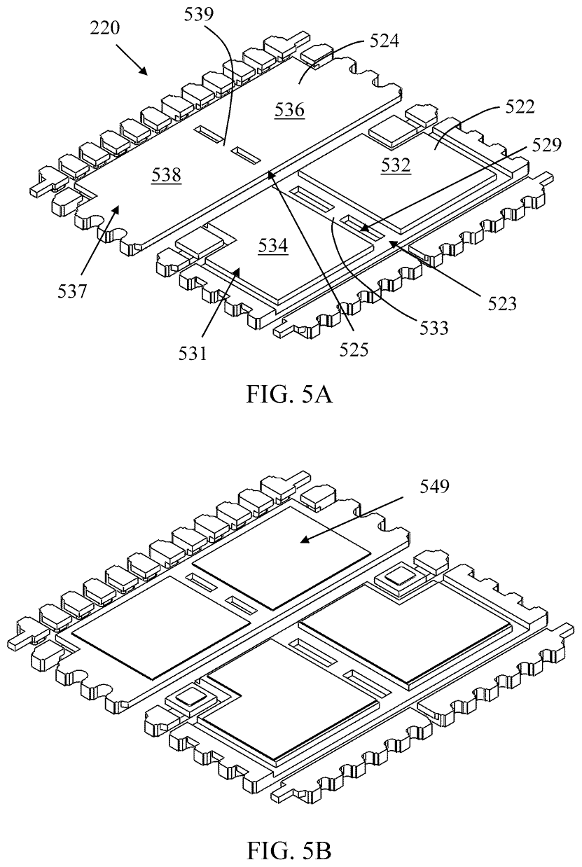

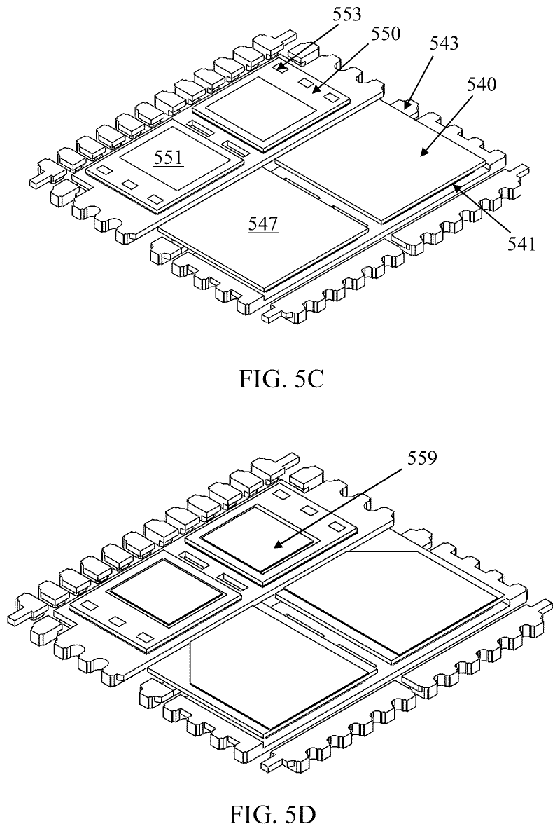

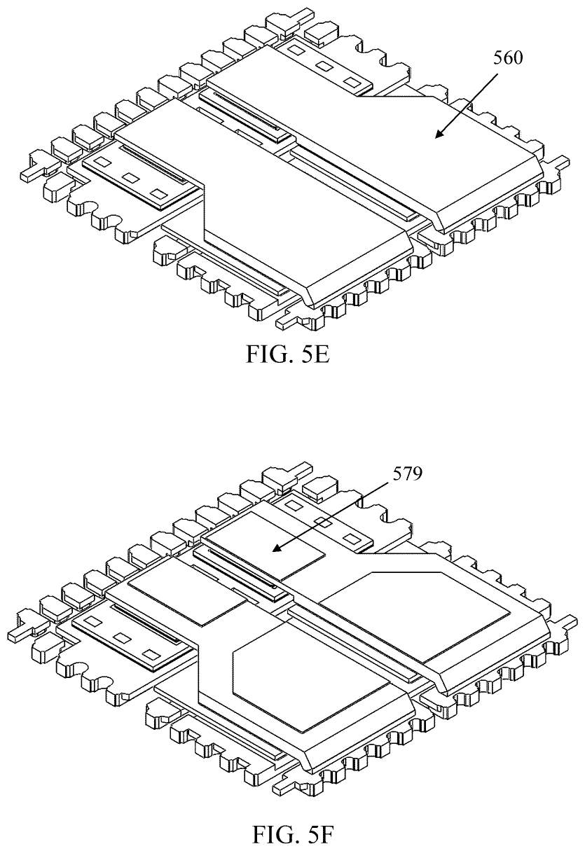

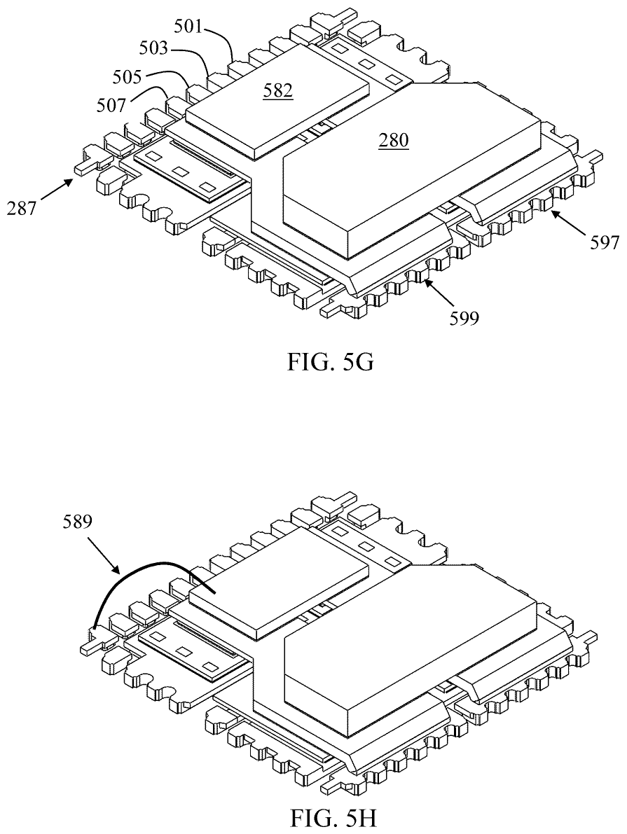

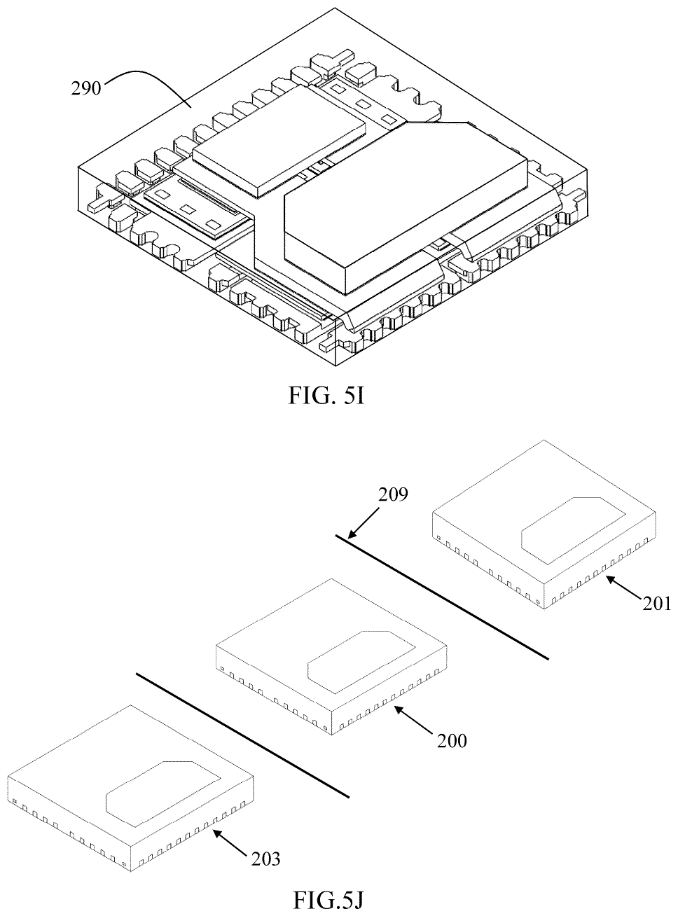

FIG. 2A is a top perspective view and FIG. 2B is a bottom perspective view of a semiconductor package 200 in examples of the present disclosure. The semiconductor package 200 comprises a lead frame 220, two or more low side field-effect transistors (FETs) 540 of FIG. 5C, two or more high side FETs 550 of FIG. 5C, two or more metal clips 560 of FIG. 5E, a metal slug 280, an integrated circuit (IC) controller 582 of FIG. 5G, and a molding encapsulation 290.

The lead frame 220 comprises a first die paddle 522 of FIG. 5A and a second die paddle 524 of FIG. 5A. In one example, the first die paddle 522 is top etched so as to form one or more cavities 523 filled with the molding encapsulation 290. In another example, the second die paddle 524 is bottom etched so as to form one or more grooves including groove 525 of FIG. 5A, filled with the molding encapsulation 290. In examples of the present disclosure, the lead frame 220 includes one or more slots 529 filled with the molding encapsulation 290 so as to facilitate locking mechanism thereby improving the integration of the lead frame 220 and the molding encapsulation 290.

Each low side FET of the two or more low side FETs 540 of FIG. 5C is flipped and attached to the first die paddle 522. Each low side FET of the two or more low side FETs 540 comprises a source electrode 541 and a gate electrode 543 on a top surface of said each low side FET of the two or more low side FETs 540. Each low side FET of the two or more low side FETs 540 comprises a drain electrode 547 on a bottom surface of said each low side FET of the two or more low side FETs 540.

Each high side FET of the two or more high side FETs 550 is attached to the second die paddle 524. Each high side FET of the two or more high side FETs 550 comprises a source electrode 551 and a gate electrode 553 on a top surface of said each high side FET of the two or more high side FETs 550.

Each metal clip of the two or more metal clips 560 connects the drain electrode 547 of a respective low side FET of the two or more low side FETs 540 to the source electrode 551 of a respective high side FET of the two or more high side FETs 550.

The metal slug 280 is positioned above the two or more low side FETs 540. Each metal clip of the two or more metal clips 560 is attached to the metal slug 280.

The IC controller 582 is positioned above the two or more high side FETs 550. Each metal clip of the two or more metal clips 560 is attached to the IC controller 582.

The molding encapsulation 290 encloses the two or more low side FETs 540, the two or more high side FETs 550, the two or more metal clips 560, a first majority portion of the metal slug 280, the IC controller 582, and a second majority portion of the lead frame 220. In examples of the present disclosure, the first majority portion refers to a percentage larger than 50%. The second majority portion refers to a percentage larger than 50%.

A first significant portion of a bottom surface of the first die paddle 522 is exposed from the molding encapsulation 290. A second significant portion of a bottom surface of the second die paddle 524 is exposed from the molding encapsulation 290. In examples of the present disclosure, the first significant portion refers to a percentage larger than 90%. The second significant portion refers to a percentage larger than 90%. A top surface of the metal slug 280 is exposed from the molding encapsulation 290.

In examples of the present disclosure, the semiconductor package 200 further comprises a plurality of bond wires 589 of FIG. 5H. The lead frame 220 further comprises a plurality of leads 287 of FIG. 5G. The plurality of bond wires 589 connect the IC controller 582 to the plurality of leads 287. The molding encapsulation 290 further encloses the plurality of bond wires 589.

The first die paddle comprises two or more paddle sections 531 of FIG. 5A and one or more connection sections 533. Though only paddle section 532 and paddle section 534 are shown in FIG. 5A, the number of the two or more paddle sections 531 may vary. Each connection section of the one or more connection sections 533 is between a first respective paddle section 532 of the two or more paddle sections 531 and a second respective paddle section 534 of the two or more paddle sections 531. Each connection section of the one or more connection sections 533 is top-etched so that a thickness of each connection section of the one or more connection sections 533 is smaller than a thickness of the first respective paddle section 532 of the two or more paddle sections 531. In examples of the present disclosure, the thickness of each connection section of the one or more connection sections 533 is 50% of the thickness of the first respective paddle section 532 of the two or more paddle sections 531.

Each connection section of the one or more connection sections 533 comprises one or more slots 529. The one or more slots 529 of each connection section of the one or more connection sections 533 are filled with the molding encapsulation 290.

The second die paddle 524 comprises two or more paddle sections 537 and one or more connection sections 539. Each connection section of the one or more connection sections 539 is between a first respective paddle section 536 of the two or more paddle sections 537 and a second respective paddle section 538 of the two or more paddle sections 537. Each connection section of the one or more connection sections 539 is bottom-etched forming a groove 525. The groove 525 is filled with the molding encapsulation 290. A thickness of each connection section of the one or more connection sections 539 is smaller than a thickness of the first respective paddle section 536 of the two or more paddle sections 537.

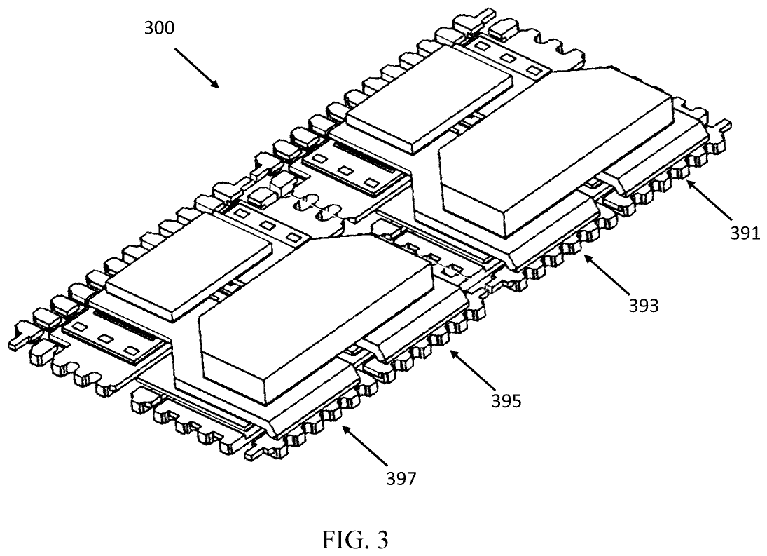

The semiconductor package comprises two or more driver devices. In one example, semiconductor package 200 of FIG. 2A comprises a first driver device 597 of FIG. 5G and a second driver device 599 of FIG. 5G. In another example, semiconductor package 300 of FIG. 3 comprises a first driver device 391, a second driver device 393, a third driver device 395, and a fourth driver device 397. Each driver device of the two or more driver devices of the semiconductor package 200 comprises a respective low side FET of the two or more low side FETs 540, a respective high side FET of the two or more high side FETs 550; and a respective metal clip of the two or more metal clips 560. Each of the two or more driver devices connects to a same Vcc pin 501 of FIG. 5G, a same TMON pin 503, a same AGND pin 505, and a same PVcc pin 507 so as to reduce the width of the semiconductor package 200 (from 5 mm by 5 mm to 5 mm by 4 mm).

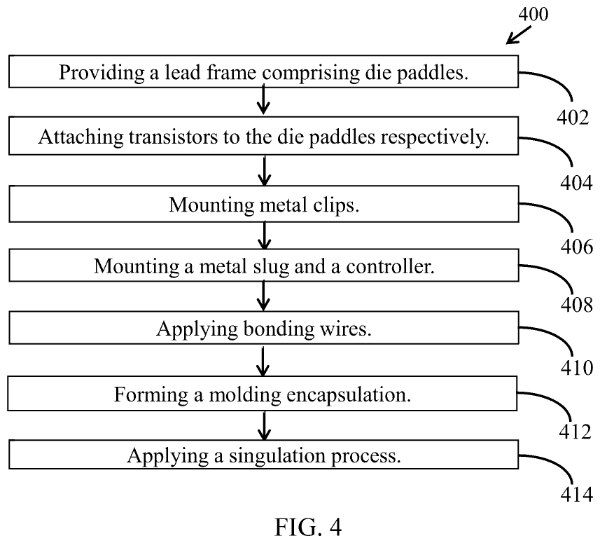

FIG. 4 is a flowchart of a process 400 to develop a semiconductor package in examples of the present disclosure. The process 400 may start from block 402.

In block 402, referring now to FIG. 5A, a lead frame 220 is provided. The lead frame 220 comprises a first die paddle 522 and a second die paddle 524. In one example, the first die paddle 522 is top etched so as to from one or more cavities 523 filled with the molding encapsulation 290. In another example, the second die paddle 524 is bottom etched so as to from one or more grooves including groove 525, filled with the molding encapsulation 290. In examples of the present disclosure, the lead frame 220 includes one or more slots 529 filled with the molding encapsulation 290 so as to facilitate locking mechanism thereby improving the integration of the lead frame 220 and the molding encapsulation 290.

The first die paddle comprises two or more paddle sections 531 and one or more connection sections 533. Though only paddle section 532 and paddle section 534 are shown in FIG. 5A, the number of the two or more paddle sections 531 may vary. Each connection section of the one or more connection sections 533 is between a first respective paddle section 532 of the two or more paddle sections 531 and a second respective paddle section 534 of the two or more paddle sections 531. Each connection section of the one or more connection sections 533 is top-etched so that a thickness of each connection section of the one or more connection sections 533 is smaller than a thickness of the first respective paddle section 532 of the two or more paddle sections 531. In examples of the present disclosure, the thickness of each connection section of the one or more connection sections 533 is 50% of the thickness of the first respective paddle section 532 of the two or more paddle sections 531.

Each connection section of the one or more connection sections 533 comprises one or more slots 529. The one or more slots 529 of each connection section of the one or more connection sections 533 are filled with the molding encapsulation 290.

The second die paddle 524 comprises two or more paddle sections 537 and one or more connection sections 539. Each connection section of the one or more connection sections 539 is between a first respective paddle section 536 of the two or more paddle sections 537 and a second respective paddle section 538 of the two or more paddle sections 537. Each connection section of the one or more connection sections 539 is bottom-etched forming a groove 525. The groove 525 is filled with the molding encapsulation 290. A thickness of each connection section of the one or more connection sections 539 is smaller than a thickness of the first respective paddle section 536 of the two or more paddle sections 537. Block 402 may be followed by block 404.

In block 404, referring now to FIGS. 5B and 5C, two or more low side FETs 540 are attached to the first die paddle 522 and two or more high side FETs 550 are attached to the second die paddle 524 by printed solder material layer 549. Each low side FET of the two or more low side FETs 540 of FIG. 5C is flipped and attached to the first die paddle 522. Each low side FET of the two or more low side FETs 540 comprises a source electrode 541 and a gate electrode 543 on a top surface of said each low side FET of the two or more low side FETs 540. Each low side FET of the two or more low side FETs 540 comprises a drain electrode 547 on a bottom surface of said each low side FET of the two or more low side FETs 540.

Each high side FET of the two or more high side FETs 550 is attached to the second die paddle 524. Each high side FET of the two or more high side FETs 550 comprises a source electrode 551 and a gate electrode 553 on a top surface of said each high side FET of the two or more high side FETs 550. Block 404 may be followed by block 406.

In block 406, referring now to FIGS. 5D and 5E, two or more metal clips are mounted by dispensed solder material layer 559. Each metal clip of the two or more metal clips 560 connects the drain electrode 547 of a respective low side FET of the two or more low side FETs 540 to the source electrode 551 of a respective high side FET of the two or more high side FETs 550. Block 406 may be followed by block 408.

In block 408, referring now to FIGS. 5F and 5G, a metal slug 280 is mounted, and an IC controller 582 is mounter by non-conductive epoxy layer 579. The metal slug 280 is positioned above the two or more low side FETs 540. Each metal clip of the two or more metal clips 560 is attached to the metal slug 280. The IC controller 582 is positioned above the two or more high side FETs 550. Each metal clip of the two or more metal clips 560 is attached to the IC controller 582. Block 408 may be followed by block 410.

In block 410, referring now to FIG. 5H, a plurality of bond wires 589 are attached. The plurality of bond wires 589 connect the IC controller 582 to the plurality of leads 287 of the lead frame 220. Block 410 may be followed by block 412.

In block 412, referring now to FIG. 5I, a molding encapsulation 290 is formed. The molding encapsulation 290 encloses the two or more low side FETs 540, the two or more high side FETs 550, the two or more metal clips 560, a first majority portion of the metal slug 280, the IC controller 582, and a second majority portion of the lead frame 220. In one example, the molding encapsulation 290 further encloses the plurality of bond wires 589. In examples of the present disclosure, the first majority portion refers to a percentage larger than 50%. The second majority portion refers to a percentage larger than 50%.

A first significant portion of a bottom surface of the first die paddle 522 is exposed from the molding encapsulation 290. A second significant portion of a bottom surface of the second die paddle 524 is exposed from the molding encapsulation 290. In examples of the present disclosure, the first significant portion refers to a percentage larger than 90%. The second significant portion refers to a percentage larger than 90%. A top surface of the metal slug 280 is exposed from the molding encapsulation 290. Block 412 may be followed by block 414.

In block 414, a singulation process 209 is applied so as to separate the semiconductor package 200 from adjacent semiconductor packages 201 and 203.

Those of ordinary skill in the art may recognize that modifications of the embodiments disclosed herein are possible. For example, a number of bond wires may vary. Other modifications may occur to those of ordinary skill in this art, and all such modifications are deemed to fall within the purview of the present invention, as defined by the claims.

1. A semiconductor package comprising:
a lead frame comprising
a first die paddle; and
a second die paddle;
two or more low side field-effect transistors (FETs), each low side FET of the two or more low side FETs being flipped and attached to the first die paddle, each low side FET of the two or more low side FETs comprising a source electrode and a gate electrode on a top surface of said each low side FET of the two or more low side FETs, and each low side FET of the two or more low side FETs comprising a drain electrode on a bottom surface of said each low side FET of the two or more low side FETs;
two or more high side FETs, each high side FET of the two or more high side FETs being attached to the second die paddle, and each high side FET of the two or more high side FETs comprising a source electrode and a gate electrode on a top surface of said each high side FET of the two or more high side FETs;
two or more metal clips, each metal clip of the two or more metal clips connecting the drain electrode of a respective low side FET of the two or more low side FETs to the source electrode of a respective high side FET of the two or more high side FETs;
a metal slug positioned above the two or more low side FETs, each metal clip of the two or more metal clips being attached to the metal slug;
an integrated circuit (IC) controller positioned above the two or more high side FETs, each metal clip of the two or more metal clips is attached to the IC controller; and
a molding encapsulation enclosing the two or more low side FETs, the two or more high side FETs, the two or more metal clips, a first majority portion of the metal slug, the IC controller, and a second majority portion of the lead frame.

2. The semiconductor package of claim 1, wherein a first significant portion of a bottom surface of the first die paddle is exposed from the molding encapsulation; a second significant portion of a bottom surface of the second die paddle is exposed from the molding encapsulation; and a top surface of the metal slug is exposed from the molding encapsulation.

3. The semiconductor package of claim 1 further comprising a plurality of bond wires;
wherein the lead frame further comprises a plurality of leads;
wherein the plurality of bond wires connect the IC controller to the plurality of leads; and
wherein the molding encapsulation further encloses the plurality of bond wires.

4. The semiconductor package of claim 1, wherein the first die paddle comprises two or more paddle sections and one or more connection sections;
wherein each connection section of the one or more connection sections is between a first respective paddle section of the two or more paddle sections and a second respective paddle section of the two or more paddle sections; and
wherein each connection section of the one or more connection sections is top-etched so that a thickness of each connection section of the one or more connection sections is smaller than a thickness of the first respective paddle section of the two or more paddle sections.

5. The semiconductor package of claim 4, wherein the thickness of each connection section of the one or more connection sections is 50% of the thickness of the first respective paddle section of the two or more paddle sections.

6. The semiconductor package of claim 4, wherein each connection section of the one or more connection sections comprises one or more slots; and
wherein the one or more slots of each connection section of the one or more connection sections are filled with the molding encapsulation.

7. The semiconductor package of claim 1, wherein the second die paddle comprises two or more paddle sections and one or more connection sections;
wherein each connection section of the one or more connection sections is between a first respective paddle section of the two or more paddle sections and a second respective paddle section of the two or more paddle sections; and
wherein each connection section of the one or more connection sections is bottom-etched forming a groove;
wherein the groove is filled with the molding encapsulation; and
wherein a thickness of each connection section of the one or more connection sections is smaller than a thickness of the first respective paddle section of the two or more paddle sections.

8. The semiconductor package of claim 1 further comprising two or more driver devices;
wherein each driver device of the two or more driver devices comprises:
a respective low side FET of the two or more low side FETs;
a respective high side FET of the two or more high side FETs; and
a respective metal clip of the two or more metal clips.

9. The semiconductor package of claim 8, wherein each of the two or more driver devices connects to a same Vcc pin, a same TMON pin, a same AGND pin, and a same PVcc pin.

10. A method for fabricating a semiconductor package, the method comprising the steps of:
providing a lead frame comprising
a first die paddle; and
a second die paddle;
attaching two or more low side field-effect transistors (FETs) to the first die paddle, each low side FET of the two or more low side FETs being flipped, each low side FET of the two or more low side FETs comprising a drain electrode on a bottom surface of said each low side FET of the two or more low side FETs, attaching two or more high side FETs to the second die paddle, and each high side FET of the two or more high side FETs comprising a source electrode and a gate electrode on a top surface of said each high side FET of the two or more high side FETs;
mounting two or more metal clips so as to connect the drain electrode of a respective low side FET of the two or more low side FETs to the source electrode of a respective high side FET of the two or more high side FETs by each metal clip of two or more metal clips;
connecting each metal clip of the two or more metal clips to a metal slug positioned above the two or more low side FETs, and connecting each metal clip of the two or more metal clips to an integrated circuit (IC) controller positioned above the two or more high side FETs;
applying a wire bonding process;
forming a molding encapsulation enclosing the two or more low side FETs, the two or more high side FETs, the two or more metal clips, a first majority portion of the metal slug, the IC controller, and a second majority portion of the lead frame; and
applying a singulation process separating the semiconductor package from adjacent semiconductor packages.

11. The method of claim 10, wherein a first significant portion of a bottom surface of the first die paddle is exposed from the molding encapsulation; a second significant portion of a bottom surface of the second die paddle is exposed from the molding encapsulation; and a top surface of the metal slug is exposed from the molding encapsulation.

12. The method of claim 10, wherein the lead frame further comprises a plurality of leads; and
wherein, during the step of applying the wire bonding process, a plurality of bond wires connect the IC controller to the plurality of leads; and
wherein the molding encapsulation further encloses the plurality of bond wires.

13. The method of claim 10, wherein the first die paddle comprises two or more paddle sections and one or more connection sections;
wherein each connection section of the one or more connection sections is between a first respective paddle section of the two or more paddle sections and a second respective paddle section of the two or more paddle sections; and
wherein each connection section of the one or more connection sections is top-etched so that a thickness of each connection section of the one or more connection sections is smaller than a thickness of the first respective paddle section of the two or more paddle sections.

14. The method of claim 13, wherein the thickness of each connection section of the one or more connection sections is 50% of the thickness of the first respective paddle section of the two or more paddle sections.

15. The method of claim 13, wherein each connection section of the one or more connection sections comprises one or more slots; and
wherein the one or more slots of each connection section of the one or more connection sections are filled with the molding encapsulation.

16. The method of claim 10, wherein the second die paddle comprises two or more paddle sections and one or more connection sections;
wherein each connection section of the one or more connection sections is between a first respective paddle section of the two or more paddle sections and a second respective paddle section of the two or more paddle sections; and
wherein each connection section of the one or more connection sections is bottom-etched forming a groove;
wherein the groove is filled with the molding encapsulation; and
wherein a thickness of each connection section of the one or more connection sections is smaller than a thickness of the first respective paddle section of the two or more paddle sections.

17. The method of claim 10 further comprising after the step of providing the lead frame, printing solder material on the lead frame; and
after the step of attaching two or more low side FETs, dispensing solder material on the two or more low side FETs and the two or more high side FETs.

18. The method of claim 10 further comprising
after the step of mounting two or more metal clips, dispensing non-conductive epoxy on the two or more metal clips.

19. The method of claim 10, wherein the semiconductor package further comprises two or more driver devices; and
wherein each driver device of the two or more driver devices comprises:
a respective low side FET of the two or more low side FETs;
a respective high side FET of the two or more high side FETs; and
a respective metal clip of the two or more metal clips.

20. The method of claim 19, wherein each of the two or more driver devices connects to a same Vcc pin, a same TMON pin, a same AGND pin, and a same PVcc pin.
